(19) United States
(12) Patent Application Publication
(10) Pub. No.: US 2004/0011463 A1
(43) Pub. Date: Jan. 22, 2004

(54) Resist stripping equipment

(76) Inventors: Toshimoto Nakagawa, Kawasaki-shi (JP); Shu Ogawa, Tokyo (JP); Satoru Morita, Tokyo (JP); Yasuyuki Kobayakawa, Tokyo (JP); Makoto Kikukawa, Yokohama-shi (JP)

Correspondence Address: ROSENTHAL & OSHA L.L.P., 1221 MCKINNEY AVENUE, SUITE 2800, HOUSTON, TX, 77010, US

(21) Appl. No.: 10/614,451

(22) Filed: Jul. 7, 2003

(30) Foreign Application Priority Data
Jul. 19, 2002 (JP) P2002-211237

(51) Int. Cl. H01L 21/306

(52) U.S. Cl. 156/345.18

(57) ABSTRACT

Resist stripping equipment includes a resist stripping system which includes a plurality of resist stripping chambers provided in a connected row arrangement and a rinse system which includes a rinse chamber. Insides of the resist stripping chambers are purged with nitrogen gas from a nitrogen gas supply system. Mixed gas which is generated in each chamber and contains a water-based resist stripping solution component is sent to a solution recovery/supply system for gas/liquid separation. Recovered resist stripping solution is returned into a stripping solution tank, while separated gas is supplied to a gas knife in each chamber and used for draining solution from a substrate.

### BACKGROUND OF THE INVENTION

1. Field of the Invention

The present invention relates to resist stripping equipment used for stripping resist on a substrate in a manufacturing process of a semiconductor or the like.

2. Related Background of the Invention

Resist materials used in a photolithography process in manufacturing processes of a semiconductor device, a substrate of a flat panel display (FPD) and the like include positive resist, which is solubilized by exposure, and negative resist, which is insolubilized by exposure. The positive resist is more widely used. A representative example of the positive resist is one essentially containing a photosensitive agent of naphthoquinone diazide and an alkali soluble resin (novolak resin).

In a final stage of the photolithography process, it is necessary to completely strip resist off the substrate. For example, the final stage of the photolithography process uses a combination of a dry ashing process with oxygen plasma and a wet stripping process with a resist stripping solution. On the substrate which has been through the dry ashing process with oxygen plasma, silicon oxide or aluminum oxide is produced. Accordingly, the subsequent wet stripping process is required to completely remove metal oxide as well as to strip resist.

Generally, as a resist stripping solution used in the resist stripping process in the manufacture of a semiconductor device or a flat panel display substrate, a solution (non-water-based resist stripping solution) of a combination of organic alkali and organic solvent is widely used. Moreover, a solution (water-based resist stripping solution) obtained by adding an appropriate amount of water into such a non-water-based resist stripping solution is also used.

Specifically, the followings are examples of the organic components used in the resist stripping solution. The examples of organic alkali are alkanolamines, diglycolamines and the like, and the examples of organic solvent are dimethyl sulfoxide, N-methyl pyrrolidone and glycol ethers. These components are used with various kinds of additives which are added thereto if necessary.

The water-based resist stripping solution contains deionized water as a major component in addition to the organic components. The non-water-based resist stripping solution is normally used at 70° C. to 90° C., while the water-based resist stripping solution is normally used at 30° C. to 65° C.

FIG. 3 is a structural diagram showing an example of conventional resist stripping equipment which uses such a resist stripping solution. Equipment 70 includes a plurality of resist stripping chambers 71 provided at multiple stages and a rinse chamber 72 adjacent to one of the resist stripping chambers 71. In each of the resist stripping chambers 71, one of sprays 91 is provided and connected to one of stripping solution tanks 73 storing resist stripping solution R0. The stripping solution tanks 73 are supplied with the resist stripping solution RO from a stripping solution supply system 81.

In the rinse chamber 72, a spray 95 connected to a deionized water tank 75 is provided. The deionized water tank 75 is supplied with deionized water M from a deionized water supply system 82. Furthermore, each of the resist stripping chambers 71 includes one of gas knives connected to a dry air supply system 83. Moreover, each of the resist stripping chambers 71 is connected to an exhaust system 84.

In the resist stripping equipment 70, while a substrate W such as a semiconductor substrate is conveyed by roller conveyors within each resist stripping chamber 71 in a direction indicated by an arrow Y in the drawing, a surface of the substrate W is sprayed with the resist stripping solution R0 from the spray 91. The resist on the substrate W is thus stripped and removed. The resist stripping solution RO containing dissolved resist is recovered into the stripping solution tank 73 and circulated to be used. The resist stripping solution R0 is then drained to a drain system 85 if necessary.

The substrate W is sprayed with dry air from the gas knife (generally referred to as “air knife” when the gas is air), and the resist stripping solution R0 on the substrate W is drained off. The substrate W is then conveyed to the subsequent resist stripping chamber 71 and lastly rinsed with water in the rinse chamber 72. In these processes, a large amount of air (mixed gas) containing mist of the resist stripping solution RO is exhausted from each of the chambers 71 and 72 by an exhaust system 84. Correspondingly, air A is taken in from the outside of the resist stripping chamber 71 at the first stage and from the outside of the rinse chamber 72.

### SUMMARY OF THE INVENTION

Regarding boiling points of the components used in the resist stripping solution, the boiling point of the organic alkali or the organic solvent is about 160° C. to 250° C., and the boiling point of water is 100° C. Accordingly, components with lower boiling points (alkanolamines and the like in the non-water-based resist stripping solution, or water in the water-based resist stripping solution) in the resist stripping solution RO are evaporated first into the mixed gas which is exhausted from the resist stripping chambers 71 of the conventional equipment 70.

The mixed gas accompanied with such evaporated components and spray mist is exhausted out of a system of the equipment by the exhaust system 84. Accordingly, concentrations of the components with lower boiling points in the resist stripping solution RO decrease, and variation in the concentrations is caused.

In this case, resist stripping performance of the resist stripping solution R0 tends to gradually deteriorate. In order to prevent this deterioration, additional operations are necessary, such as active replenishment of an effective component of the resist stripping solution R0 and a change of the resist stripping solution R0 at a certain frequency.

These operations increase use of the resist stripping solution R0 and require complicated operations and work for controlling the concentrations thereof. The operations also require exhaust gas treatment equipment for treating the organic components in large quantities of mixed gas which has been exhausted.

The present invention was made in the light of the above problems, and an object of the present invention is to provide resist stripping equipment capable of preventing variation in the concentrations of effective components in the resist stripping solution, reducing use of the resist stripping solution, and reducing an amount of the exhaust gas to be treated.

In order to solve the above-described problems, resist stripping equipment of the present invention is characterized by including (1) a resist stripping chamber in which a substrate covered with resist is accommodated and resist stripping solution is supplied onto the substrate; (2) a gas/liquid separation block which is connected to the resist stripping chamber, and in which mixed gas containing a resist stripping solution component in the resist stripping chamber is introduced and separated from the resist stripping solution component; and (3) a recovered resist stripping solution supply block which is connected to the gas/liquid separation block and supplies the separated resist stripping solution component to the resist stripping chamber.

In the resist stripping equipment thus constituted, the resist stripping solution is supplied onto the substrate accommodated in the resist stripping chamber, and resist covering the substrate is stripped and removed. In this process, the mixed gas of spray mist; a component with a lower boiling point (resist stripping solution component) which is an evaporated mist component of the resist stripping solution; air (atmosphere); and the like are generated.

This mixed gas is introduced into the gas/liquid separation block, for example, by an exhaust system connected to the resist stripping chamber and separated into gas and the resist stripping solution component. The resist stripping solution thus separated and recovered is supplied again to the resist stripping chamber by the recovered resist stripping solution supply block.

Specifically, for example, the resist stripping chamber is provided with a spray (device) connected to a supply solution tank of the resist stripping solution, and a recovery block of the recovered resist stripping solution component is provided between the supply solution tank and the gas/liquid separation block.

The resist stripping chamber includes a gas spout unit, and the resist stripping equipment preferably further includes (4) a separated gas supply unit which receives gas separated from the resist stripping solution component in the liquid/gas separation block and supplies the gas to the gas spout unit.

In this manner, as the air (atmosphere) discharged from the gas spout unit into the system is circulated in the system, the ratio of remaining gas such as nitrogen gas to oxygen gas in the recovered and separated gas gradually increases. Accordingly, gas in the system is deactivated, and deterioration of the resist stripping solution is reduced. Moreover, a moisture increase in the gas suppresses drying of the substrate.

More preferably, the gas spout unit is disposed facing the substrate. The gas spout unit thus disposed can serve as a gas knife which drains the resist stripping solution from the substrate. As previously described, the gas knife has been hitherto supplied with dry air from the outside. However, in the present invention, the separated gas from the mixed gas recovered from the resist stripping chamber can be used as a gas source for the gas knife.

The knowledge of the inventors of the present invention revealed that if dry air is sprayed on a surface of a substrate like the conventional equipment, the resist stripping solution on the substrate tends to be excessively dried.

For example, in a state where the substrate is substantially completely dried, resist dissolved in the resist stripping solution may be deposited. Accordingly, a thin film of the resist may remain on the substrate, and problems may be caused in an after-treatment of the substrate.

In contrast to this, in the present invention, since the separated gas, which may contain moisture, is supplied on the surface of the substrate, the substrate is prevented from excessively being dried, thus the above described conventional disadvantages are eliminated. Moreover, amounts of the evaporated components with lower boiling points in the resist stripping solution can be considerably reduced. Consequently, variation in concentrations of the resist stripping solution can be reduced.

More preferably, the resist stripping equipment includes (5) an inert gas supply unit which is connected to the resist stripping chamber and supplies inert gas into the resist stripping chamber.

For the inert gas, which is not particularly limited, nitrogen (N₂) gas, noble gas, or the like is used. From the viewpoints of industrial availability and costs, nitrogen gas is useful.

The inventors of the present invention also obtained the following knowledge by conducting various investigations on the conventional resist stripping equipment from another viewpoint in addition to the viewpoint of reduction in consumption of the resist stripping solution as previously described.

Specifically, when butyldiglycol (hereinafter, referred to as “BDG”) is used as an organic solvent which is mainly included in the resist stripping solution and amines such as monoethanolamine (hereinafter, referred to as “MEA”) is used as an alkali which is also mainly included in the resist stripping solution, the BDG is oxidized by oxygen (O₂) gas in the air and reacts with the MEA to generate oxamide.

The oxamide itself is not active in stripping resist. When the concentration of oxamide excessively increases, crystals of the oxamide are deposited and the concentrations of active amines tend to decrease. Moreover, the deposited crystals may lead to generation of particles or clogging of pipes, or the deposited crystals may become an unstable factor for a concentration measurement system.

Alternatively, amines such as MEA react with carbon dioxide (CO₂) gas in the air to generate carbamic acid. The concentrations of the active amines thus decrease. Carbamic acid itself is not active in stripping resist.

Furthermore, since the carbamic acid has low solubility to a water-based resist stripping solution and tends to have a specific gravity and a viscosity different from those of the water-based resist stripping solution, the resist stripping solution can be separated into two phases. Accordingly, there is a possibility that resist on the substrate may be unevenly stripped.

The resist stripping solution tends to color and change in absorbance by the resist dissolving in the resist stripping solution with the processing. By utilizing such a tendency, the concentration of dissolved resist can be measured and controlled.

However, even in a state where the resist does not dissolve in the resist stripping solution, it was confirmed that the resist stripping solution colors as time passes when the resist stripping solution is in contact with air. Such coloring, which is considered to be caused by natural oxidation, has an adverse effect on the measurement of the concentration of dissolved resist by the absorbance measurement and may reduce control accuracy because of measurement errors.

In contrast to this, when the resist stripping chamber is supplied with the inert gas such as nitrogen gas from the inert gas supply unit, air within the resist stripping chamber is purged by the inert gas and the contact of the resist stripping chamber and air is cut off.

Ideally, the resist stripping chamber is completely sealed from the outside. However, actually complete sealing involves difficulties. Even in such a case, if gas replacement is actively performed by supplying the inert gas such as nitrogen gas to the chambers, amounts of oxygen gas and carbon dioxide gas absorbed into the resist stripping solution can be reduced to a level which is virtually insignificant.

More specifically, it is useful if the resist stripping solution is a water-based resist stripping solution, and if the resist stripping equipment includes a plurality of resist stripping chambers which are provided in multiple stages and communicates with each other; a rinse chamber which is provided to communicate with one of the plurality of resist stripping chambers at a last stage and supplied with water; a gas/liquid separation block connected to one of the plurality of resist stripping chambers at a first stage; and an inert gas supply unit connected to the rinse chamber.

The resist stripping equipment thus constituted includes the resist stripping chambers at multiple stages, which are provided in a connected row arrangement, and the rinse chamber further connected to the resist stripping chamber at the last stage. While a substrate is conveyed sequentially through these chambers, resist on the substrate is stripped and removed by the water-based resist stripping solution, and lastly the substrate is rinsed with water. Each of the chambers communicate with each other, and gas is exhausted from the chamber at the first stage, which is connected to the gas/liquid separation block, and taken in at the rinse chamber located at the last stage, which is connected to the inert gas supply unit.

Accordingly, nitrogen gas or the like flows in a direction opposite to the direction of conveying the substrate and purges all the chambers. Moreover, since the nitrogen gas or the like passes the rinse chamber, the nitrogen gas containing moisture is circulated in the system.

Therefore, an amount of water evaporated from the water-based resist stripping solution is considerably reduced, and reduction of the concentration of water can be thus suppressed. Furthermore, separated gas recovered from mixed gas is given an adequate amount of moisture, and the wet gas thus obtained is sprayed on the substrate from a gas spout unit.

In this case, preferably, the resist stripping chamber at the first stage and the gas/liquid separation block are connected to each other through a pipe provided with a damper, a flow rate adjustment valve and the like. Moreover, a pressure switch or the like is preferably provided, which adjusts valve travel of the damper, the flow rate adjustment valve or the like based on pressure in the rinse chamber, to which the inert gas is supplied.

Alternatively, it is useful if the resist stripping solution is a non-water-based resist stripping solution, and if the resist stripping equipment includes a plurality of resist stripping chambers which is provided in multiple stages and communicates with each other; a rinse chamber which is provided to communicate with one of the plurality of resist stripping chambers at a last stage and supplied with water; a gas/liquid separation block connected to one of the plurality of resist stripping chambers at a first stage; and an inert gas supply unit connected to one of the plurality of resist stripping chambers at the last stage.

The resist stripping equipment thus constituted includes the resist stripping chambers at multiple stages, which are provided in a connected row arrangement, and the rinse chamber further connected to one of the resist stripping chambers at the last stage. While a substrate is conveyed sequentially through these chambers, resist is stripped and removed by the non-water-based resist stripping solution, and lastly the substrate is rinsed with water.

Each of the chambers communicates with each other, and gas is exhausted from the chamber at the first stage, which is connected to the gas/liquid separation block, and taken in at the resist stripping chamber at the last stage, which is connected to the inert gas supply unit. Accordingly, inert gas such as nitrogen gas flows in a direction opposite to the direction of conveying the substrate and purges insides of all the resist stripping chambers with the nitrogen gas or the like. Moreover, since the nitrogen gas or the like does not pass through the rinse chamber, water is prevented from entering the system where the non-water-based resist stripping solution is circulated, and moisture absorption into the non-water-based resist stripping solution can be thus suppressed.

In this case, preferably, the resist stripping chamber at the first stage and the gas/liquid separation block are connected to each other through a pipe provided with a damper, a flow rate adjustment valve and the like. Moreover, a pressure switch or the like is preferably provided, which adjusts valve travel of the damper, the flow rate adjustment valve or the like based on pressure in the resist stripping chamber at the last stage, to which the inert gas is supplied. It is desirable that the rinse chamber is connected to an independent exhaust system.

### BRIEF DESCRIPTION OF THE DRAWINGS

FIG. 1 is a structural diagram showing a first embodiment of resist stripping equipment according to the present invention.

FIG. 2 is a structural diagram showing a second embodiment of resist stripping equipment according to the present invention.

FIG. 3 is a structural diagram showing an example of conventional resist stripping equipment.

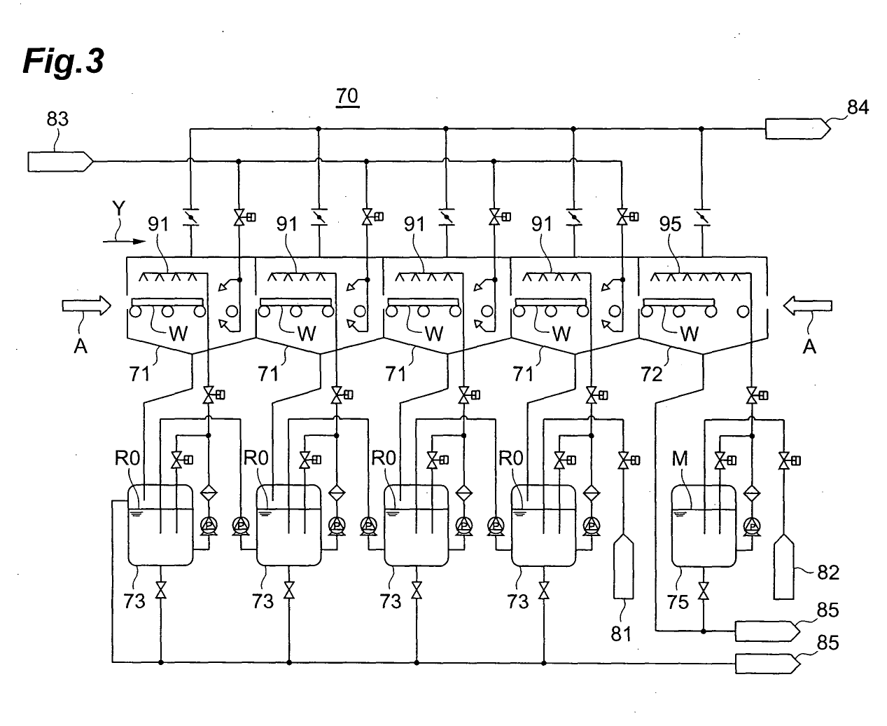

### DESCRIPTION OF THE PREFERRED EMBODIMENTS

Hereinafter, a description will be given of embodiments in detail. The same components will be given the same reference numerals, and the redundant explanation will be omitted. Positional relationships, such as up and down, right and left, are based on the positional relationships in the drawings unless otherwise noted. The dimensional proportions are not limited to those shown in the drawings.

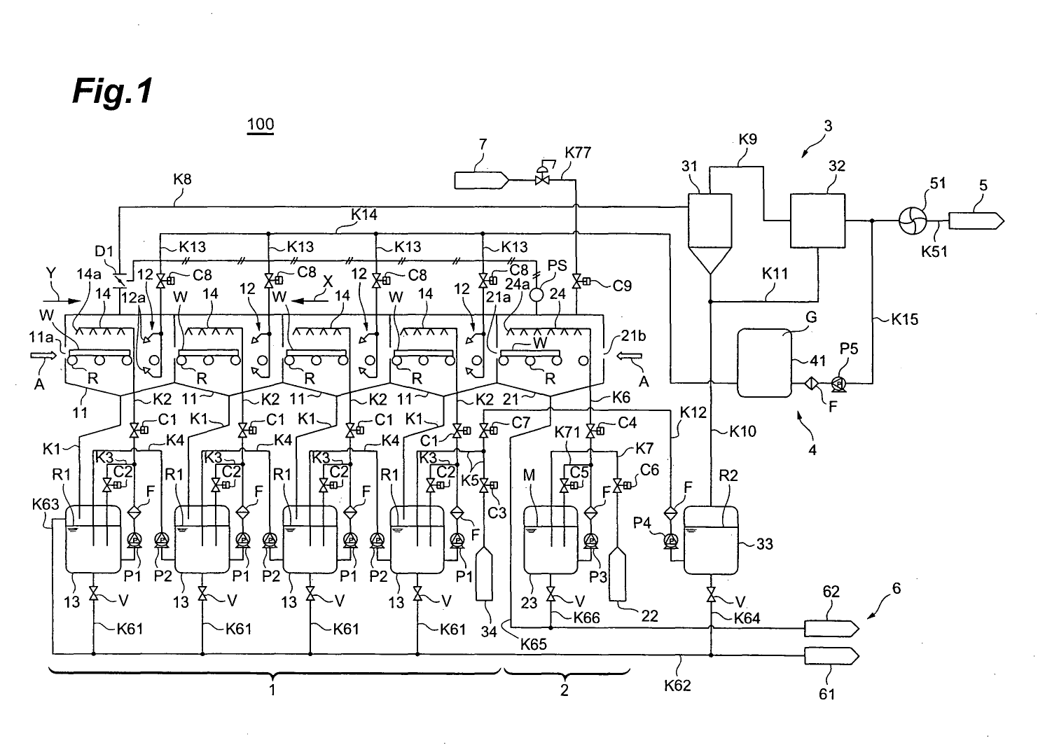

Resist stripping equipment 100 in FIG. 1 is an equipment system which strips resist covering a substrate W of FPDs typified by liquid crystal displays or the like with a water-based resist stripping solution R1. The resist stripping equipment 100 includes a resist stripping system 1, a rinse system 2, a solution recovery/supply system 3, a gas recovery/supply system 4, an exhaust system 5, a drain system 6, and a nitrogen gas supply system 7.

The resist stripping system 1 includes a plurality of resist stripping chambers 11 in a connected row arrangement. The bottom of each of the resist stripping chambers 11 is connected to one of stripping solution tanks 13 through one of pipes K1. The stripping solution tanks 13 are connected to a resist stripping solution supply system 34. Each of the resist stripping chambers 11 has an entrance 11a for the substrate W.

In each resist stripping chambers 11, rotatable roller conveyors R, on which the substrate W is placed, are provided. Above these roller conveyors R, one of sprays 14 is disposed. Each spray 14 includes a plurality of nozzles 14a arranged so as to face the substrate W. The sprays 14 are connected to the respective stripping solution tanks 13 through pipes K2. Each of the pipes K2 is provided with one of flow rate adjustment valves C1, one of filters F, and one of pumps P1.

In each resist stripping chamber 11, one of gas knives (gas spout units) 12, each of which includes gas nozzles 12a, are provided after the spray 14. The gas nozzles 12a are disposed so as to face both surfaces of the substrate W.

Between the flow rate adjustment valve C1 and the filter F in each pipe K2, one of branch pipes K3 for circulation/agitation and circulation/filtration is connected. Each branch pipe K3 includes a flow rate adjustment valves C2 and is inserted into the corresponding stripping solution tank 13. Each of the stripping solution tanks 13 is connected to each other with one of pipes K4 including one of pumps P2. One of the stripping solution tanks 13 connected to the resist stripping chamber 11 at the last stage is connected to the above-mentioned resist stripping supply system 34 through a pipe K5 provided with a flow rate adjustment valve C3.

On the other hand, the rinse system includes a rinse chamber 21 connected to the resist stripping chamber 11 at the last stage. The rinse chamber 21 has an entrance 21a and an exit 21b for the substrate W. The roller conveyors R are also provided in the rinse chamber 21. Above these roller conveyors R, a spray 24 including a plurality of nozzles 24a is disposed. The nozzles 24a are arranged to face the substrate W in the rinse chamber 21.

The spray 24 is connected to a deionized water tank 23 through a pipe K6 provided with a flow rate adjustment valve C4, a filter F, and a pump P3. A branch pipe K71 for circulation/agitation and circulation/filtration is connected between the flow rate adjustment valve C4 and the filter F in the pipe K6. The branch pipe K71 includes a flow rate adjustment valve C5 and is inserted into the deionized water tank 23.

The deionized water tank 23 is further connected to a deionized water supply system 22 through a pipe K7 provided with a flow rate adjustment valve C6. The rinse chamber 21 is connected to the nitrogen gas supply system 7 through a pipe K77 provided with a flow rate adjustment valve C9.

The solution recovery/supply system 3 includes a cyclone 31, a condenser 32, and a stripping solution recovery tank (recovery unit) 33. The cyclone 31 is connected to the resist stripping chamber 11 at the first stage through a pipe K8 provided with a dumper D1. The condenser 32 is connected to the cyclone 31 through a pipe K9. The stripping solution recovery tank 33 is connected to the cyclone 31 through a pipe K10.

The dumper D1 is connected to a pressure switch PS provided for the rinse chamber 21. The pipe K10 is connected to a pipe K11 which is connected to the condenser 32. The condenser 32 is connected to the exhaust system 5 through a pipe K51 provided with an exhaust blower 51. Accordingly, gas in the resist stripping chambers 11 and the rinse chamber 21 is introduced to the solution recovery/supply system 3.

The stripping solution recovery tank 33 is connected to the pipe K5, which connects the stripping solution tank 13 at the last stage and the resist stripping solution supply system 34, through a pipe K12. The pipe K12 is provided with a flow rate adjustment valve C7, a filter F, and a pump P4. As described above, the cyclone 31 and the condenser 32 constitute a gas/solution separation block. The stripping solution recovery tank 33 and the stripping solution tanks 13 constitute a recovered resist stripping solution supply block.

On the other hand, the gas recovery supply system 4 includes a gas tank 41. The gas tank 41 is connected to a pipe K14 provided with branch pipes K13, each of which is connected to the respective resist stripping chambers 11 and provided with one of flow rate adjustment valves C8. Each of the branch pipes K13 is connected to the gas knife 12 of the respective resist stripping chambers 11.

The gas tank 41 is connected to a pipe K15 provided with a filter F and a compressor P5. The pipe K15 is connected to the pipe K51, which connects the condenser 32 and the exhaust system 5.

The drain system 6 includes a stripping solution recovery unit 61 and a deionized water recovery unit 62. The stripping solution recovery unit 61 is connected to the stripping solution tanks 13 through a pipe K62, which is connected to branch pipes K61 each including one of open/close valves V.

The stripping solution tank 13 at the first stage is connected to a pipe K63 for overflow which is connected to the pipe K62. The pipe K62 is further connected to the stripping solution recovery tank 33 through a branch pipe K64 including an open/close valve V.

The deionized water recovery unit 62 is connected to a pipe K65 which is connected to the bottom of the rinse chamber 21. The pipe K65 is connected to the deionized water tank 23 through a pipe K66 including an open/close valve V.

Hereinafter, a description will be given of an example of resist processing for the substrate W by use of the resist stripping equipment 100 thus constituted.

Prior to a resist stripping process for the substrate W, the water-based resist stripping solution R1 is supplied from the resist stripping solution supply system 34 to the stripping solution tank 13 at the last stage through the pipe KS. The water-based resist stripping solution R1 is transferred by an operation of the pump P2 sequentially to the stripping solution tanks 13 at the previous stages through the pipes K4. Deionized water M is supplied from the deionized water supply system 22 to the deionized water tank 23 through the pipe K7.

Here, the water-based resist stripping solution R1 is not particularly limited. A solution generally used can be employed, for example, a mixed solution of alkanolamines, dimethyl sulfoxide, and deionized water; a mixed solution of alkanolamines, N-methyl-pyrrolidone, and deionized water; a mixed solution of alkanolamines, glycol ethers, and deionized water; and other solutions produced by adding various additives into these solutions.

As stock solutions used for the water-based resist stripping solution R1, in the above-described examples, used are dimethyl sulfoxide type stock solution, N-methyl-pyrrolidone type stock solution, diglycol type stock solution, alkanolamines stock solution, a mixed stock solution of alkanolamine and a glycolether type solvent, other stock solutions produced by adding water and various additives into these stock solutions, and the like.

Examples of alkanolamines are monoethanolamine, diethanolamine, triethanolamine, N,N-dimethylethanolamine, N,N-diethylethanolamine, aminoethylethanolamine, N-methyl-N,N-diethanolamine, N,N-dibutylethanolamine, N-methylethanolamine, and 3-amino-1-propanol.

Examples of glycol ethers are butyldiglycol, diethylene glycol monomethyl ether, diethylene glycol monoethyl ether, and diethylene glycol monopropyl ether. Furthermore, examples of the additives are catechol, a reducing agent, an anticorrosive, and a chelating agent.

The rinse chamber 21 is supplied with nitrogen gas from the nitrogen gas supply system 7 through the pipe K77. At this moment, a flow rate of the nitrogen gas is set to a predetermined flow rate by properly adjusting a valve travel of the flow rate adjustment valve C9. Simultaneously, the exhaust blower 51 is operated to exhaust gas from the resist stripping chamber 11 at the first stage. By performing these operations, insides of the resist stripping chambers 11 and the rinse chamber 12, which communicate with each other with the entrances 11a and 21a, are purged with nitrogen gas.

Air outside the system can be taken in the chambers from the entrance 11a of the resist stripping chamber 11 at the first stage and the exit 21b of the rinse chamber 21. Preferably, an amount of nitrogen gas supplied to the rinse chamber 21 is adjusted so that an amount of the taken air does not disadvantageously increase.

An amount of exhaust gas from the resist stripping chamber 11 at the first stage is regulated by adjusting valve travel of the damper D1 of the pipe K8 with a control signal from the pressure switch PS attached to the rinse chamber 21. The pressure switch PS monitors an inner pressure of the rinse chamber 21 and transmits to the damper D1 a valve travel signal in accordance with, for example, a difference of the monitored inner pressure and a predetermined pressure.

A plurality of the substrates W are introduced one by one into the resist stripping system 1 at regular intervals from the entrance 11a of the resist stripping chamber 11 at the first stage and then conveyed on the roller conveyors R to the following stages (in a direction indicated by an arrow Y in the drawing). Simultaneously, the pumps P1 connected to the respective stripping solution tanks 13 are operated, and each flow rate adjustment valve C1 is adjusted at a predetermined valve travel. Accordingly, the water-based resist stripping solution R1 filtered by the filters F is spouted from the sprays 14 onto the substrates W. At this moment, valve travels of the flow rate adjust valves C2 are properly adjusted if necessary, and a supply amount of the solution to the sprays 14 is thus regulated.

With the spray, mist of the water-based resist stripping solution R1 is generated. Moreover, since the water-based resist stripping solution R1 is normally used at a temperature of 30° C. to 65° C., a resist stripping process can be performed at a low temperature where the substrates W are little affected by heat. However, part of water, which is a major component with a lower boiling point of the water-based resist stripping solution R1, evaporates.

Thus, mixed gas including nitrogen gas which contains the water-based resist stripping solution R1 component is generated in each resist stripping chamber 11. As described later, since water mist and water vapor are generated in the rinse chamber 21, the mixed gas contains these water mist and vapor.

In this state, the supply of nitrogen gas to the rinse chamber 21 and the exhaustion of gas from the resist stripping chamber 11 are continuously carried out, and airflow occurs in a direction indicated by an arrow X in the drawing. Accordingly, the mixed gas is continuously exhausted from the resist stripping chamber 11 at the first stage through the pipe K8 and introduced to the cyclone 31 of the solution recovery supply system 3.

For the cyclone 31, for example, a cyclone for gas/liquid separation is employed. The cyclone 31 separates a large portion of the water-based resist stripping solution R1, which is a liquid component of the mixed gas, from a gas component of the introduced mixed gas. A recovered resist stripping solution R2 thus separated is transferred to the stripping solution recovery tank 33 through the pipe K10. On the other hand, the gas containing a little amount of the water-based resist stripping solution R1 component is introduced into the condenser 32 through the pipe K9.

Gas/liquid separation is further performed in the condenser 32 so that the separated gas does not have excessively low or high humidity (moisture), in other words, so that the separated gas G is wet gas containing adequate moisture. For example, a condition in which the separated gas G has a relative humidity of 60% to 90% is adopted.

The recovered resist stripping solution R2 which has been condensed and recovered in the condenser 32 is transferred to the stripping solution recovery tank 33 through the pipes K11 and K10. With an operation of the pump P4, the recovered resist stripping solution R2 is filtered by the filter F while passing through the pipe K12 and then flowed into the pipe K5 to be sequentially supplied to each stripping solution tank 13.

On the other hand, with an operation of the compressor P5, at least part of the gas (separated gas G) obtained by the gas/liquid separation in the condenser 32 is filtered while passing through the pipes K51 and K15, and then introduced into the gas tank 41 to be appropriately stored. This separated gas G is transferred to the pipe K14 and then supplied to the gas knives 12 through the respective pipes K13 at a certain flow rate regulated by the respective flow rate adjustment valves C8.

The substrates W are sprayed with the water-based resist stripping solution R1 from the sprays 14 while being conveyed on the roller conveyors R. Accordingly, a large part of resist on the substrates W is dissolved and removed. The water-based resist stripping solution R1 containing the dissolved resist is returned from the bottoms of the resist stripping chambers 11 to the stripping solution tanks 13 through the pipes K1 to be circulated and used. When the amount of the solution in the stripping solution tanks 13 is reduced, the water-based resist stripping solution R1 is replenished from the resist stripping solution supply system 34 to the stripping solution tanks 13.

In the replenishment, at least one of various types of components such as new solution, stock solution, deionized water, and additives may be supplied. If the water-based resist stripping solution R1 is excessively supplied, or if necessary, the water-based resist stripping solution R1 overflowed from the stripping solution tank 13 at the first stage is transferred to the drain system 6 through the pipe K63. Furthermore, when the water-based resist stripping solution R1 needs to be replaced, the water-based resist stripping solution R1 is appropriately drained to the drain system 6 through the pipes K61 and K62.

The separated gas G is sprayed from the gas knives 12 onto the surfaces of each substrate W which has passed under the spray 14, and the water-based resist stripping solution R1 on the substrates W is thus drained off. As previously described, the separated gas G is wet nitrogen gas containing adequate moisture. Having the surface which is not completely dried nor getting condensation thereon, each substrate W is conveyed to the resist stripping chamber 11 at the subsequent stage.

Subsequently, each substrate W undergoes the resist dissolution and removal process in the plurality of resist stripping chambers 11 at the following stages similarly to the above described process. The substrates W are then introduced into the rinse chamber 21 through the entrance 21a. In the rinse chamber 21, the deionized water M supplied from the deionized water tank 23 through the pipe K6 is spouted onto the substrates W from the spray 24, and the water-based resist stripping solution R1 remaining on the substrates W is thus rinsed off. The substrates W are then conveyed outside from the exit 21b. The water-based resist stripping solution R1 which has been rinsed off is transferred together with the ionized water M to the drain system 6 through the pipe 65.

According to the resist stripping equipment 100 as described above, the water-based resist stripping solution R1 component which has turned into the mixed gas in the resist stripping chambers 11 is separated and recovered from the mixed gas as the recovered resist stripping solution R2 by the solution recovery/supply system 3 including the cyclone 31 and the condenser 32. The recovered resist stripping solution R2 is then reused in the resist stripping process for the substrates W through the stripping solution recovery tank 33 and the stripping solution tanks 13.

Accordingly, the consumption of water-based resist stripping solution R1 by exhaust of the mixed gas can be prevented, in other words, the water-based resist stripping solution R1 can be prevented from being exhausted outside the system with the processing. Consequently, it is possible to suppress the deterioration of resist stripping performance caused by the reduction of water concentration in the water-based resist stripping solution R1 which is supplied onto the substrates W.

Moreover, since O₂ gas and CO₂ gas in a little air mixed in from the outside of the system is absorbed into the water-based resist stripping solution R1, the separated gas G which is recovered becomes in a similar state to inert gas which has reduced residuals of O₂ gas and CO₂ gas. Accordingly, the deterioration of the resist stripping performance can be suppressed. In other words, the sufficient resist stripping performance can be maintained for a long time.

Moreover, the frequency of replenishing the new solution, deionized water, the stock solution, or the like to the stripping solution tanks 13 can be considerably reduced. Accordingly, there is an advantage that the complicated operations and work involved therein can be omitted. Furthermore, use of the water-based resist stripping solution R1 can be considerably reduced.

Still furthermore, since the gas knives 12 use the separated gas G recovered from the mixed gas, dry air is unnecessary. In addition to this, compared to the conventional equipment which exhausts the mixed gas without any utilization, considerable reduction in the amount of exhaust gas to be processed, and miniaturized and simplified gas processing equipment for processing the exhaust gas can be achieved. Moreover, the equipment, which is non-explosion proof equipment, can further improve in safety.

Since the insides of the resist stripping chambers 11 provided at multiple stages and the rinse chamber 21 communicating with the resist stripping chambers 11 are purged with nitrogen gas, the contact of the water-based resist stripping solution R1 and air can be adequately cut off.

Accordingly, when the water-based resist stripping solution R1 contains glycol ethers such as BDG and amines such as MEA, generation of oxamide (for example, N,N-bis (2-hydroxyethyl) oxamide which may be generated when the water-based resist stripping solution R1 contains BDG and MEA) by a reaction of the glycol ethers and oxygen gas in the air can be suppressed. Consequently, generation of particles by deposition of oxamide crystals, clogging of the pipes, and instabilities of the concentration measuring system can be prevented.

Generation of carbamic acid (for example, 2-hydroxyethyl carbamate, and the like) by a reaction of MEA and carbon dioxide in the air can be suppressed. Consequently, unevenness of the resist stripping on the substrates W, which is caused by two-phase separation of the water-based resist stripping solution R1, can be prevented from occurring. Furthermore, the remainder of resist in a thin film can be prevented from occurring.

Since generation of oxamide or carbamic acid can be suppressed as described above, consumption of MEA, BDG or the like, which are effective components in the water-based resist stripping solution R1, can be suppressed. Accordingly, reduction and deterioration of the water-based resist stripping performance can be further prevented. Moreover, since the concentration of oxygen dissolved in the water-based resist stripping solution R1 can be reduced, when each substrate W is provided with a metallic base layer, the corrosion thereof can be prevented.

Moreover, when the liquid properties are controlled by measuring the concentration of resist dissolved in the water-based resist stripping solution R1 with the absorbance measurement, since the contact of the water-based resist stripping solution R1 and air is adequately cut off, coloring of the water-based resist stripping solution R1 caused by oxidation can be prevented. Accordingly, the accuracy of the absorbance measurement can be prevented from declining, thus high accuracy can be maintained in controlling the solution with the dissolved resist concentration.

Since the separated gas G containing adequate moisture is supplied to the gas knives 12 to drain the water-based resist stripping solution R1 from the substrates W, the substrates W are not completely dried while being conveyed through the resist stripping chambers 11 and the rinse chamber 21.

Accordingly, the dissolved resist can be prevented from being deposited on the substrates W during the resist stripping process and the rinse process. Consequently, the adverse effect on the substrates W in the after-treatment can be suppressed. Furthermore, the substrates W can be prevented not only from being dried up in being drained off the water-based resist stripping solution R1, but also from getting condensation of the liquid component (moisture) in the separated gas G thereon. Consequently, the water-based resist stripping solution R1 can be adequately drained off.

Moreover, since nitrogen gas is supplied to the rinse chamber 21, wet nitrogen gas is easily supplied to the resist stripping system 1. Accordingly, evaporation of water in the water-based resist stripping solution R1 and insufficiency of moisture in the separation gas G can be prevented.

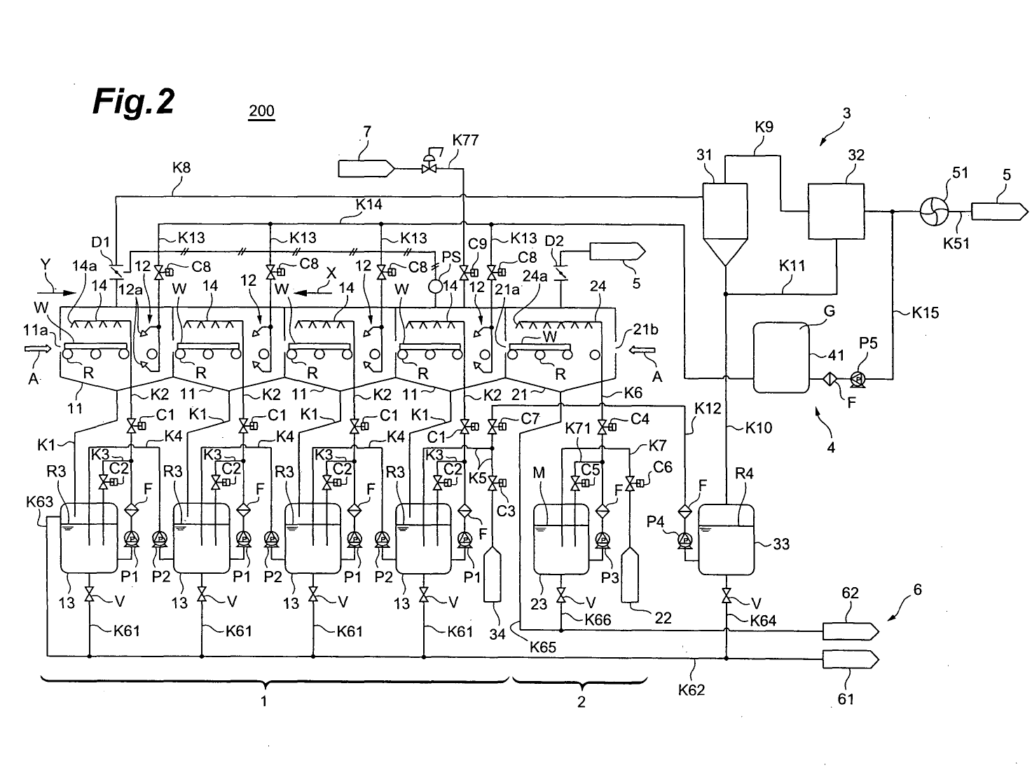

Resist stripping equipment 200 in FIG. 2 is constituted similarly to the resist stripping equipment 100 shown in FIG. 1 with the exception that non-water-based resist stripping solution R3 is used instead of the water-based resist stripping solution R1; recovered resist stripping solution R4 of non-water-based type is obtained instead of the recovered resist stripping solution R3 of water-based type; the pressure switch PS connected to the damper D1 and the nitrogen gas supply system 7 are not connected to the rinse chamber 21 but to the resist stripping chamber 11 at the last stage; and the rinse chamber 21 is connected to an exhaust system 5 through a damper D2.

In the resist stripping equipment 200, the non-water-based resist stripping solution R3, which is normally maintained at a constant temperature of 70° C. to 90° C., is supplied onto the substrates W. For the non-water-based resist stripping solution R3, generally, components equivalent to those of the water-based resist stripping solution R1 which is previously described can be used except deionized water.

Nitrogen gas is supplied to the resist stripping chamber 11 at the last stage, and gas is exhausted from the resist stripping chamber 11 at the first stage. Since the gas in the rinse chamber 21 is separately and independently exhausted, the flow of gas between the resist stripping system 1 and the rinse system 2 is cut off, and the gas phases thereof are isolated from each other.

Accordingly, the mixed gas which is discharged from the resist stripping chambers 11 and introduced into the cyclone 31 does not contain water but mainly contains components with a lower boiling point (for example, amines such as MEA) which has been evaporated first from the non-water-based resist stripping solution R3 or spray mist of the non-water-based resist stripping solution R3. Consequently, the separated gas G which does not contain water but contains the adequate amount of the non-water-based resist stripping solution R3 component as moisture is separated and recovered from the mixed gas, and supplied to the gas knives 12.

According to this resist stripping equipment 200, the non-water-based resist stripping solution R3 which has turned into the mixed gas is recovered as the recovered resist stripping solution R4 in the solution recovery/supply system 3 to be reused, and simultaneously, the separated gas G which has been separated and recovered from the mixed gas G is reused. Therefore, the followings can be achieve, specifically, reduction in consumption and use of the solution; prevention of gas exhausting out of the system; prevention of evaporation of a component with a lower boiling point; prevention of deterioration of the resist stripping performance; reduction in the frequency of replenishing the solution and the work thereof; non-use of dry air; and reduction in the amount of exhaust gas to be processed.

Since the insides of all resist stripping chambers 11 are purged with nitrogen gas, the contact of the non-water-based resist stripping solution R3 and air is prevented. Accordingly, generation of deteriorated components and coloring of the solution can be suppressed. Furthermore, if the separated gas G to be recovered is adequately wet gas with the non-water-based resist stripping solution R3 component (organic component), when draining the solution from the substrates W with the gas knives 12, the substrates W can be prevented from drying as well as getting condensation thereon. Since the operations and mechanisms which show the effectiveness thereof are equivalent to those of the resist stripping equipment 100, the detailed explanation thereof will be omitted.

Moreover, the resist stripping chamber 11 at the last stage is connected to the nitrogen gas supply system 7 so that gas in the rinse chamber 21 is not flowed into the resist stripping chambers 11. Accordingly, water is prevented from mixing into the non-water-based resist stripping solution R3. Thus variation in the properties of the non-water-based resist stripping solution R3 can be suppressed.

The present invention is not limited to the above-described embodiments, and various modifications can be made without departing from the scope of the invention. For example, the number of the resist stripping chambers 11 may be one. The control of the amount of exhaust gas with the pressure switch PS and the damper D1 may be replaced by the flow rate control alone by using gas mass balance. The separated gas G may be spouted into the resist stripping chambers 11 without using the gas knives 12. In this case, the gas tank 41 is allowed to be omitted.

Furthermore, instead of being recovered into the gas tank 41, the separated gas G may be supported or held by solid or liquid by means of attachment, absorption, or the like. Still furthermore, the recovered resist stripping solutions R2 and R4 may be transferred directly into the stripping solution tanks 13 without using the stripping solution recovery tank 33.

As described above, according to the resist stripping equipment of the present invention, the resist stripping solution can be prevented from varying in concentration of the effective component thereof. Moreover, reduction in use of the resist stripping solution, as well as reduction in the amount of exhaust gas to be processed, can be achieved. If the resist stripping equipment is provided with an inert gas supply unit, deterioration of the resist stripping solution can be prevented.

What is claimed is:

1. Resist stripping equipment, comprising:
a resist stripping chamber in which a substrate covered with resist is accommodated and resist stripping solution is supplied onto the substrate;
a gas/liquid separation block which is connected to the resist stripping chamber, and to which mixed gas containing a resist stripping solution component in the resist stripping chamber is introduced, and in which the resist stripping solution component of the mixed gas is separated; and
a recovered resist stripping solution supply block which is connected to the gas/liquid separation block and supplies the separated resist stripping solution component to the resist stripping chamber.

2. The resist stripping equipment of claim 1, further comprising:
a separated gas supply unit which receives gas separated from the resist stripping solution component in the liquid/gas separation block and supplies the gas to the gas spout unit,
wherein the resist stripping chamber includes a gas spout unit.

3. The resist stripping equipment of claim 2, wherein the gas spout unit is disposed facing the substrate.

4. The resist stripping equipment of claim 1, further comprising:
an inert gas supply unit which is connected to the resist stripping chamber and supplies inert gas into the resist stripping chamber.

5. The resist stripping equipment of claim 4, comprising:
a plurality of the resist stripping chambers provided in multiple stages to communicate with each other;
a rinse chamber provided to communicate with one of the plurality of resist stripping chambers at a last stage, the rinse chamber being supplied with water;
the gas/liquid separation block connected to one of the plurality of resist stripping chambers at a first stage; and
the inert gas supply unit connected to the rinse chamber,
wherein the resist stripping solution is water-based resist stripping solution.

6. The resist stripping equipment of claim 4, comprising:
a plurality of the resist stripping chambers provided in multiple stages to communicate with each other;
a rinse chamber provided to communicate with one of the plurality of resist stripping chambers at a last stage, the rinse chamber being supplied with water;
the gas/liquid separation block connected to one of the plurality of resist stripping chambers at a first stage; and
the inert gas supply unit connected to one of the plurality of resist stripping chambers at the last stage,
wherein the resist stripping solution is non-water-based resist stripping solution.
